(19) United States
(12) Patent Application Publication
(10) Pub. No.: US 2002/0177264 A1
(43) Pub. Date: Nov. 28, 2002

(54) Reducing threshold voltage roll-up/roll-off effect for MOSFETS

(75) Inventors: Hiroyuki Akatsu, Yorktown Heights, NY (US); Satoshi Inaba, Peekskill, NY (US); Ryota Katsumata, Poughkeepsie, NY (US); Cheruvu S. Murthy, Hopewell Junction, NY (US); Rajesh Rengarajan, Poughkeepsie, NY (US); Paul A. Ronsheim, Hopewell Junction, NY (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY (US)

(21) Appl. No.: 09/866,397

(22) Filed: May 25, 2001

(51) Int. Cl. H01L 21/8238

(52) U.S. Cl. 438/199; 438/223; 438/229

(57) ABSTRACT

MOSFETS are formed by implanting at least a portion of a semiconductor substrate with a depart of a first type to form a first well region, annealing the first well region, implanting the annealed first well region with nitrogen; forming a gate insulator above at least a portion of the first well region; and providing a gate electrode above the gate oxide and providing source/drain regions in the substrate below the gate oxide about the gate electrode.

### FIELD OF THE INVENTION

The present invention relates to fabricating MOSFETS and especially MOSFET that are employed for DRAM Sense Amplifiers and Analog Circuits. More particularly, the present invention is concerned with reducing the threshold voltage roll-up/roll-off effect for the MOSFETS. The present invention employs a thermal anneal after forming a well followed by N₂ ion implanting before forming a gate insulator.

### BACKGROUND OF THE INVENTION

1. Field effect transistors (FETs) have become the dominant active devices for very

large scale integration (VLSI) and ultra large scale integration (ULSI) applications in view of the high performance, high density and low power characteristics of integrated circuit FETs. In fact, much research and development has involved improving the speed and density of FETs and on lowering their power consumption.

The most common configuration of FET devices is the MOSFET which typically comprises source and drain regions in a semiconductor substrate at a first surface level, and a gate region located therebetween. The gate includes an insulator on the first substrate surface between the source and drain regions, with a gate effects. Short Channel Effect refers to the difference in FET threshold voltage, Vt, between an FET at nominal channel length and one of minimum channel length. It is desirable to minimize the differences, i.e. to have a smaller value of “SCE”.

“Rollup” refers to the difference in threshold voltage between a device with a very long channel length (typically about 10 μm), to that of a device with a nominal channel length. Typically the threshold voltage “rolls up” as the length becomes shorter. Again, it is desirable to minimize the difference.

Vt roll-up characteristics (Reverse short channel effect) is particularly undesirable for DRAM peripheral circuit, because sense amplifier circuits can only tolerate small Vt mismatches caused by the variation of gate length. Thus, less Vt roll-up and less Vt roll-off are preferable for sense amplifiers.

It would therefore be desirable to suppress Vt roll-off and roll-up.

### SUMMARY OF THE INVENTION

The present invention addresses the problem of short channel effect. More particularly, the present invention reduces the threshold voltage (Vt) roll-up/roll-off effect for MOSFETS. The present invention provides a method of forming a MOSFET, which comprises:

(a) providing a semiconductor substrate,

(b) implanting at least a portion of the substrate with a first dopant species of a first type to form a first well region,

(c) annealing the first well region,

(d) implanting the annealed first well region with nitrogen,

(e) after the nitrogen implantation, forming a gate insulator above at least a portion of the first well region, and

(f) providing a gate electrode above the gate insulator and providing source/drain regions in the substrate below the insulator about the gate electrode.

The present invention also relates to a MOSFET obtained by the above-disclosed process.

Still other objects and advantages of the present invention will become readily apparent by those skilled in the art from the following detailed description, wherein it is shown and described preferred embodiments of the invention, simply by way of illustration of the best mode contemplated of carrying out the invention. As will be realized the invention is capable of other and different embodiments, and its several details are capable of modifications in various obvious respects, without departing from the invention. Accordingly, the description is to be regarded as illustrative in nature and not as restrictive.

### SUMMARY OF DRAWING

FIGS. 1-9 are schematic diagrams of a semiconductor structure prepared according to the present invention at different stage of its fabrication.

FIGS. 10 and 11 illustrate Vt roll-off/roll-up characteristics for nFET according to the present invention as compared to nFETs prepared according to process outside the scope of the present invention.

FIGS. 12 and 13 illustrate Vt roll-off/roll-up characteristics for pFET according to the present invention as compared to pFETs prepared according to processes outside the scope of the present invention.

### BEST AND VARIOUS MODES FOR CARRYING OUT INVENTION

In order to facilitate an understanding of the present invention reference will be made to the drawings.

In FIG. 1 a semiconductor substrate 1 such as monocrystalline silicon is selectively implanted with a first dopant species of a first conductive type while masking the portions of the substrate with a mask 2 such as a photoresist layer. When the dopant of the first type is a p-type dopant, the dopant of the second type will be a n-type dopant and vice versa. Suitable p-type dopants for silicon are indium and boron and suitable n-type dopants for silicon are antimony, phosphorous, and arsenic.

The dopant of the first type is employed to form a first well region 3. The dosage of the dopant is typically about 1×10¹²/cm² to about 1×10¹³/cm² and more typically about 5×10¹²/cm²to about 8×10¹²/cm².

The depth of the ion implantation is typically about 100 to about 300 nanometers.

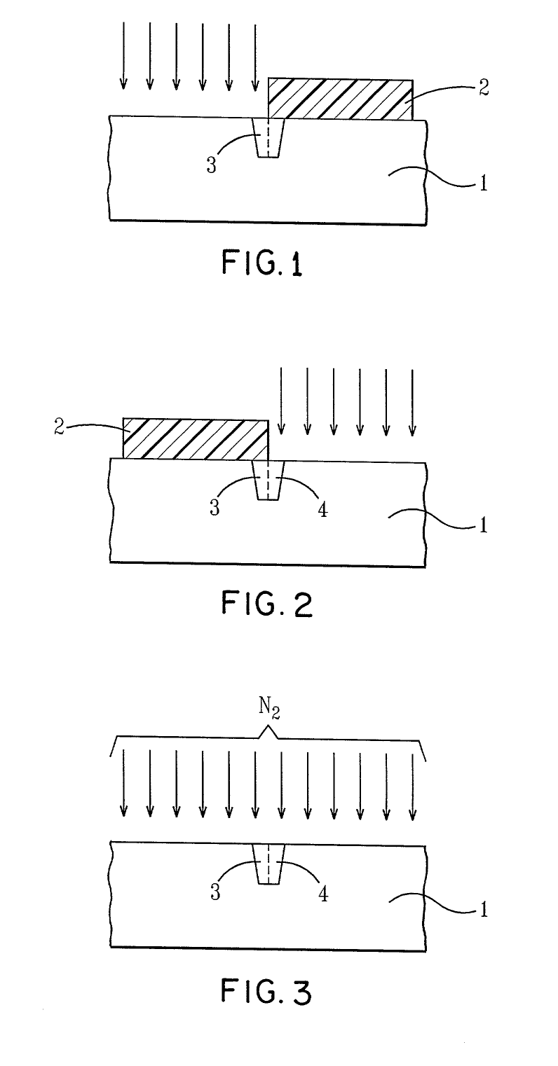

If desired, and optionally, as illustrated in FIGS. 2, a second well region 4 can be formed by ion implanting a second dopant of a second and opposite conductive type as the dopant of the first type. The dosage of the dopant of the second type is typically about 1×10¹² cm² to about 1×10¹³/cm² and more typically about 3×10¹²/cm² to about 8×10¹²/cm². The depth of this ion implantation is typically about 100 to about 300 nanometers.

According to the present invention the structure is subjected to a high temperature anneal at about 850° C. to about 1050° C., a typical example being about 1000° C., and preferably a rapid thermal anneal at these temperatures for up to about 1 minute, more typically about 1 second to about 30 seconds, and preferably about 5 to about 10 seconds, a typical example being about 5 seconds.

Next, implanting nitrogen into the annealed well region (2) as illustrated in FIG. 3. The dosage of the N₂ implanting is about 1×10¹⁴ to about 5×10¹⁴/cm² and more typically about 1.0×10¹⁴/cm² to about 3.0×10¹⁴/cm², a typical example being about 1.4E14. The nitrogen is typically implanted employing power of about 10 to about 20 KeV, a typical example being 12 KeV.

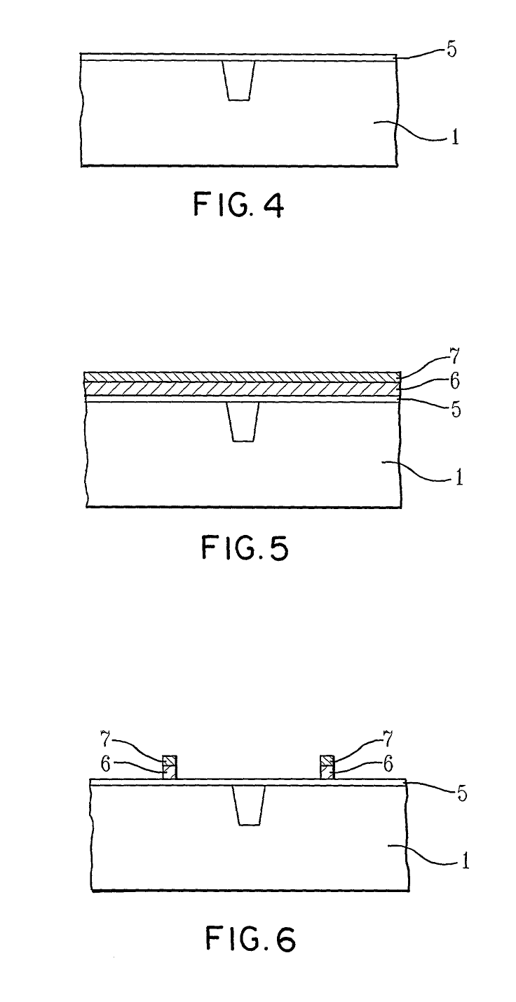

Next, as illustrated in FIG. 4, a gate insulator 5 such as silicon dioxide is formed on the substrate 1. A gate oxide can be formed by oxidization of the silicon substrate 1. The insulator 5 is typically about 1.5 to about 6.0 nanometers thick.

A gate electrode 6 is then formed. For example, as illustrated in FIG. 5, a gate stack of a polycrystalline silicon layer 6 and a low resistance contact layer 7 such as tungsten-silicon is deposited.

The gate 6 is then defined such as by reactive ion etching (RIE) See FIG. 6. Sidewall insulation (not shown) such as silicon dioxide and/or silicon nitride can be provided. This can be formed by well-known techniques and such need be described herein in any detail.

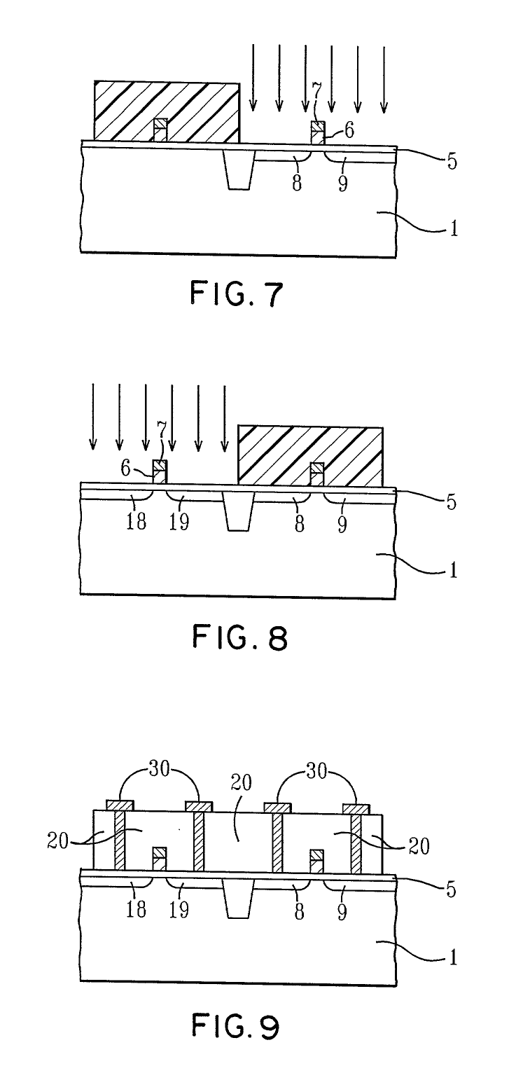

As shown in FIG. 7, source and drain regions 8 and 9 are formed by implanting dopants of the first conductively type. Halo implantation can also be carried out if desired. It may be desirable to activate the source (drain regions also using rapid thermal annealing (RTA)) of the type described above.

As shown in FIG. 8, source and drain regions 18 and 19 are formed by implanting dopants of the second conductively type. Halo implantation can also be carried out if desired. It may be desirable to activate the source (drain regions using rapid thermal annealing as described above).

Next as illustrated in FIG. 9, insulation 20 such as silicate glass such as baron-phosphorous doped silicate glass can be deposited. Contact formation and metallization 30 can then be carried out by well-known technology.

By applying this invention, both Vt roll-off and roll-up are suppressed by the combination of well anneal and N₂ implantation prior to gate oxidation. Therefore, enough margin for mass production will be obtained.

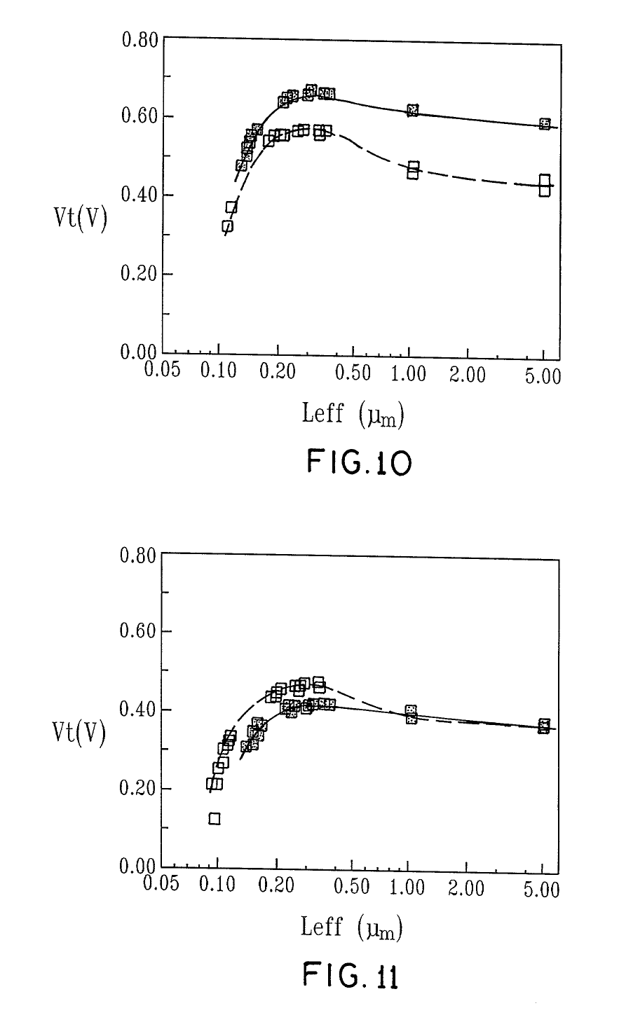

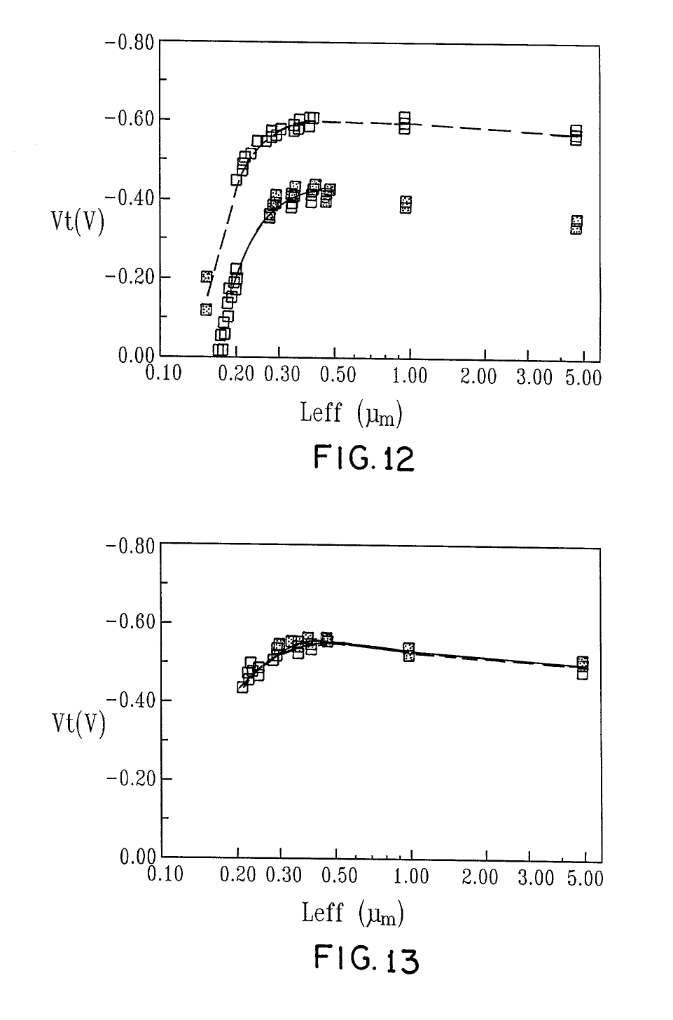

This is illustrated by a comparison of FIGS. 10 and 11, and a comparison of FIGS. 12 and 13.

FIGS. 10 and 11 show device Vt roll-off/roll-up characteristics of nFET device. In FIG. 10, no N₂ implant is employed. The solid line are results for well RTA and the dashed line without well RTA.

The well RTA suppresses Vt roll-up in the nFET, but significant Vt discrepancy even in the long channel region is observed.

FIG. 11 illustrates using the N₂ implant. The solid line are results employing well RTA while the dashed line are results without well RTA.

The Vt roll-up is suppressed with the combination of well RTA and N₂ implant, and there is no difference in long channel Vt.

FIGS. 12 and 13 show device Vt roll-off/roll-up characteristics of pFET device. In FIG. 12, no N₂ implant is employed. The solid lines are results for well RTA and the dashed line without well RTA.

The well RTA suppresses Vt roll-up in the pFET, but significant Vt discrepancy even in the long channel region is observed.

FIG. 13 illustrates using the N₂ implant. The solid lines are results employing well RTA while the dashed line are results without well RTA.

The Vt roll-up is suppressed with the combination of well RTA and N₂ implant, and there is no difference in long channel Vt.

These flat Vt roll-off/roll-up characteristics are suitable for DRAM sense amplifier or general Analog circuit (i.e., differential amplifier), because Vt sensitivity for Lpoly fluctuation can be minimized by using such flat Vt roll-off/roll-up characteristics. (Vt is almost constant even if Lpoly fluctuates.) To achieve this characteristic, N₂ implant with selectively masking for such analog circuit portion is carried out.

The foregoing description of the invention illustrates and describes the present invention. Additionally, the disclosure shows and describes only the preferred embodiments of the invention but, as mentioned above, it is to be understood that the invention is capable of use in various other combinations, modifications, and environments and is capable of changes or modifications within the scope of the inventive concept as expressed herein, commensurate with the above teachings and/or the skill or knowledge of the relevant art. The embodiments described hereinabove are further intended to explain best modes known of practicing the invention and to enable others skilled in the art to utilize the invention in such, or other, embodiments and with the various modifications required by the particular application or uses of the invention. Accordingly, the description is not intended to limit the invention opt the form disclosed herein. Also, it is intended that the appended claims be construed to include alternative embodiments.

What is claimed is:

1. A method of forming a MOSFET, which comprises:
(a) providing a semiconductor substrate,
(b) implanting at least a portion of said substrate with a first dopant species of a first type form a first well region,
(c) annealing the first well region,
(d) implanting the annealed first well region with nitrogen,
(e) after the nitrogen implantation, forming a gate insulator above at least a portion of the first well region , and
(f) providing a gate electrode above the gate insulator and providing source/drain regions in the substrate below the gate insulator about the gate electrode.

2. The method of claim 1 wherein:
(i) a second well region is formed between steps (b) and (c) by implanting a different portion of the substrate with a second dopant species of a second type, the second dopant species being of different conductivity type from the first dopant species, and wherein
(ii) the second well region is also annealed in step (C) and implanted with nitrogen in step (d).

3. The method of claim 2 wherein step (e) further comprises forming a gate insulator over the second well region.

4. The method of claim 3 wherein step (f) further comprises providing a second gate electrode above the gate insulator over the second well region and providing source/drain regions in the substrate below the gate insulator about the second gate electrode.

5. The method of claim 1 wherein the concentration of the first dopant is about 1×10¹²/cm² to about 1×10¹³/cm².

6. The method of claim 1 wherein the semiconductor substrate comprises silicon.

7. The method of claim 1 wherein the insulator comprises silicon dioxide.

8. The method of claim 1 wherein the gate comprises polycrystalline silicon.

9. The method of claim 1 wherein the concentration of the nitrogen implantation is about 1×10¹⁴ to about 5×10¹⁴/cm².

10. The method of claim 1 wherein the annealing is rapid thermal annealing.

11. The method of claim 10 wherein the rapid thermal annealing comprises employing temperatures of at least about 800° C. for times up to about 1 minute.

12. The method of claim 10 wherein the rapid thermal annealing comprises employing temperatures of about 850° C. to about 1050° C. for times up to about 1 second to about 10 seconds.

13. A MOSFET obtained by the method of claim 1.
